(19) United States
(12) Patent Application Publication
(10) Pub. No.: US 2013/0300509 A1
(43) Pub. Date: Nov. 14, 2013

(54) FREQUENCY TUNING APPARATUS, OPERATING METHOD THEREOF, AND RF CIRCUIT INCLUDING THE FREQUENCY TUNING APPARATUS

(71) Applicants: SAMSUNG ELECTRONICS CO., LTD., Suwon-Si (KR); GWANGJU INSTITUTE OF SCIENCE AND TECHNOLOGY, Buk-gu (KR)

(72) Inventors: Young-bae KIM, Seoul (KR); Chang-jung KIM, Yongin-si (KR); Sang-su PARK, Gwangju (KR); Hyun-sang HWANG, Gwangju (KR)

(73) Assignees: GWANGJU INSTITUTE OF SCIENCE AND TECHNOLOGY, Buk-gu (KR); SAMSUNG ELECTRONICS CO., LTD., Suwon-Si (KR)

(21) Appl. No.: 13/746,090

(22) Filed: Jan. 21, 2013

(30) Foreign Application Priority Data
May 9, 2012 (KR) 10-2012-0049270

(51) Int. Cl. H03L 7/00

(52) U.S. Cl. CPC H03L 7/00
USPC 331/34

(57) ABSTRACT

A frequency tuning apparatus may include an oscillator and a memory element connected to the oscillator. The memory element may have a variable resistance. An oscillation frequency of the oscillator may vary according to a resistance state of the memory element. The oscillator may be a ring oscillator. The memory element may be connected to an input terminal or a power terminal of the oscillator.

### CROSS-REFERENCE TO RELATED APPLICATION

This application claims the benefit of Korean Patent Application No. 10-2012-0049270, filed on May 9, 2012, in the Korean Intellectual Property Office, the disclosure of which is incorporated herein in its entirety by reference.

### BACKGROUND

1. Field

At least one example embodiment relates to frequency tuning apparatuses, operating methods thereof, and/or radio frequency (RF) circuits including the frequency tuning apparatuses.

2. Description of the Related Art

Wireless communication systems transfer information at a specific frequency band. One wireless communication system may need to use a plurality of frequency bands to transfer information. Generally, cellular phones usually use about 2 to 4 different frequency bands. However, micro-strip or strip line filters used in cellular phones operate at an invariable frequency band, and thus multiple filters are needed to use various frequency bands. A filter capable of tuning to multiple frequency bands may reduce the number of filters in the whole system, which may scale down a system and reduce manufacturing costs thereof.

A conventional voltage controlled oscillator (VCO) having a differential structure may include a resonance unit, the resonance unit including an inductor circuit and a capacitor circuit, an oscillation unit for providing the resonance unit with negative resistance and establishing an oscillation condition, and a current source for supplying a predetermined current to the resonance unit and the oscillation unit. Such a VCO is disadvantageously large and expensive. Meanwhile, a filter system employing a microelectro-mechanical system (MEMS) technology requires an RF switch, an RF tunable capacitor, and an RF inductor, which are not easily integrated.

### SUMMARY

At least one example embodiment provides frequency tuning apparatuses having simple structures capable of tuning to a frequency stably.

At least one example embodiment provides frequency tuning apparatuses having high performance and high reliability.

At least one example embodiment provides frequency tuning apparatuses capable of reducing power consumption.

At least one example embodiment provides frequency tuning apparatuses which may be easily operated using a relatively simple method.

At least one example embodiment provides RF circuits (for example, RF filters) including the frequency tuning apparatuses.

At least one example embodiment provides methods of operating the frequency tuning apparatuses.

Additional aspects will be set forth in part in the description which follows and, in part, will be apparent from the description, or may be learned by practice of the example embodiments.

According to at least one example embodiment, a frequency tuning apparatus includes: an oscillator; and a memory element connected to the oscillator and having a variable resistance, an oscillation frequency of the oscillator varying according to a resistance state of the memory element.

According to at least one example embodiment, the memory element may be a multi-bit memory.

According to at least one example embodiment, the memory element may have a plurality of OFF states.

According to at least one example embodiment, the resistance state of the memory element may vary according to a reset voltage.

According to at least one example embodiment, the memory element may include: a first electrode and a second electrode; and a memory layer between the first electrode and the second electrode, wherein a resistance of the memory layer varies according to a voltage applied to the memory layer.

According to at least one example embodiment, the memory layer may include an oxide.

According to at least one example embodiment, the memory layer may have a single layer structure or a multi-layer structure.

According to at least one example embodiment, if the memory layer has the multi-layer structure, then the memory layer may include an oxygen-supplying layer and an oxygen-exchanging layer.

According to at least one example embodiment, an oxygen concentration of the oxygen-exchanging layer may be higher than that of the oxygen-supplying layer.

According to at least one example embodiment, at least one of the oxygen-supplying layer and the oxygen-exchanging layer may include at least one of Ta oxide, Zr oxide, Y oxide, yttria-stabilized zirconia (YSZ), Ti oxide, Hf oxide, Mn oxide, Mg oxide, and a mixture thereof.

According to at least one example embodiment, the oscillator may be a ring oscillator.

According to at least one example embodiment, he oscillator may include: a ring type circuit in which a plurality of inverters are connected to each other in a ring configuration; and an input terminal and an output terminal connected to the ring type circuit.

According to at least one example embodiment, the memory element may be connected to the input terminal.

According to at least one example embodiment, the memory element may be connected between the input terminal and at least one of the plurality of inverters.

According to at least one example embodiment, the ring type circuit may further include a logic gate, and the oscillator may further include an enable terminal connected to the logic gate.

According to at least one example embodiment, the logic gate may be a NAND gate.

According to at least one example embodiment, the frequency tuning apparatus may further include an output inverter connected between the ring type circuit and an output terminal.

According to at least one example embodiment, the frequency tuning apparatus may further include a frequency divider connected between the ring type circuit and the output inverter.

According to at least one example embodiment, the frequency tuning apparatus may further include a power terminal (or power source) connected to the frequency divider.

According to at least one example embodiment, the power terminal (or power source) may be connected to the output inverter.

According to at least one example embodiment, the oscillator may further include a power terminal (or power source) connected between the ring type circuit and the output terminal, wherein the memory element is connected to the power terminal (or power source).

According to at least one example embodiment, the frequency tuning apparatus may further include a frequency divider connected between the power terminal (or power source) and the ring type circuit.

According to at least one example embodiment, the frequency tuning apparatus may further include an output inverter connected between the frequency divider and the output terminal.

According to another example embodiment, a radio frequency (RF) circuit may include the frequency tuning apparatus.

According to at least one example embodiment, the RF circuit may be an RF filter.

According to another example embodiment, a method of operating the frequency tuning apparatus may include: varying a resistance state of the memory element; and operating the oscillator according to the resistance state.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view of a frequency tuning apparatus according to an example embodiment;

FIGS. 2 through 5 are detailed circuit diagrams of the frequency tuning apparatus of FIG. 1, according to at least one example embodiment;

FIG. 6 is an exemplary circuit diagram showing a connection relationship between a non-volatile memory element and an inverter of a frequency tuning apparatus according to an example embodiment;

FIGS. 7 through 11 are cross-sectional views of various structures of a non-volatile memory element used in a frequency tuning apparatus according to an example embodiment;

FIG. 12 is a graph of a voltage-resistance characteristic of a non-volatile memory element having a structure of FIG. 8;

FIG. 13 is a graph of variations of ON and OFF resistances of a non-volatile memory element having a structure of FIG. 8 for each of switching conditions;

FIG. 14 is a graph of a variation of an oscillation frequency of a frequency tuning apparatus including a non-volatile memory element with respect to set and reset voltages of the non-volatile memory element according to an example embodiment;

FIG. 15 is a waveform diagram of a variation of an oscillation frequency of a frequency tuning apparatus including a non-volatile memory element with respect to set and reset voltages of the non-volatile memory element according to an example embodiment; and

FIG. 16 is a graph of a variation of an oscillation frequency with respect to a change of a voltage applied to a power terminal without a non-volatile memory element of a frequency tuning apparatus having a circuit construction of FIG. 5.

### DETAILED DESCRIPTION OF EXAMPLE EMBODIMENTS

Various example embodiments will now be described more fully with reference to the accompanying drawings in which example embodiments are shown.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a”, “an”, and “the” are intended to include the plural forms as well, unless the context clearly indicates otherwise. It will be further understood that the terms “includes”, “including”, “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects of the present description. As used herein, the term “and/or” includes any and all combinations of one or more of the associated listed items. Expressions such as “at least one of”, when preceding a list of elements, modify the entire list of elements and do not modify the individual elements of the list.

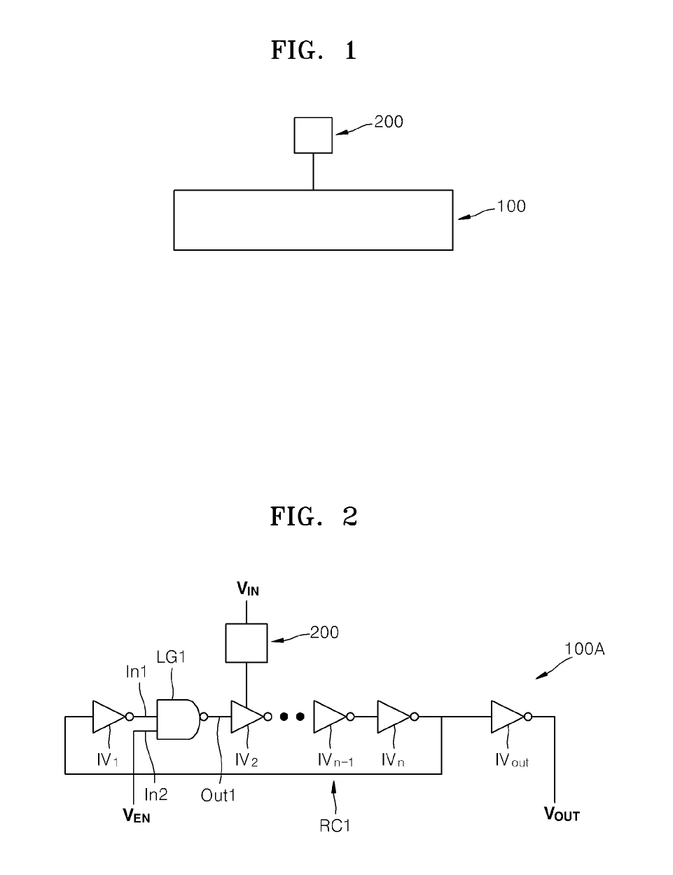

FIG. 1 is a schematic view of a frequency tuning apparatus according to an example embodiment.

Referring to FIG. 1, the frequency tuning apparatus (i.e., a device capable of tuning a frequency) according to an example embodiment may include an oscillator 100 and a memory element. The memory element may be a non-volatile memory element 200 connected to the oscillator 100. Although example embodiments are described with reference to a non-volatile memory element, other types of memory may be used, such as a volatile memory element. The oscillator 100 may be, for example, a ring oscillator. The non-volatile memory element 200 may have a resistance change characteristic (i.e., a variable resistance). An oscillation frequency of the oscillator 100 may vary according to a resistance state of the non-volatile memory element 200. The non-volatile memory element 200 may have a multi-bit memory characteristic. In this case, the non-volatile memory element 200 may have four or more different resistance states. Thus, the oscillation frequency of the oscillator 100 may have four or more variations. However, the non-volatile memory element 200 is not limited to having a characteristic of a multi-bit memory. That is, the non-volatile memory element 200 may have a characteristic of a single-bit memory. In this case, the non-volatile memory element 200 may have two different resistance states, and the oscillator 100 may have two different oscillation frequencies.

The frequency tuning apparatus of FIG. 1 will now be described in more detail with reference to FIGS. 2 through 5. Each of ring oscillators 100A-100C of FIGS. 2 through 5 corresponds to the oscillator 100 of FIG. 1.

FIGS. 2 through 5 are detailed circuit diagrams of the frequency tuning apparatus of FIG. 1, according to at least one example embodiment. Referring to FIG. 2, the ring oscillator 100A may include a ring type circuit RC1 in which a plurality of inverters IV1-IVn are connected to each other in a ring configuration. The ring oscillator 100A may have a ring structure in which the inverters IV1-IVn are connected in series to each other and in which an output end of the last inverter IVn is connected to an input end of the first inverter IV1. The ring type circuit RC1 may further include a logic gate LG1. The logic gate LG1 may be, for example, a Not AND (NAND) gate. The logic gate LG1 may be connected between two adjacent inverters among the inverters IV1-IVn, for example, between the first inverter IV1 and the second inverter IV2. The logic gate LG1 may include two input ends (hereinafter referred to as a first input end and a second input end) In1 and In2 and an output end Out1. One of the two input ends 1n1 and In2 of the logic gate LG1, for example, the first input end Int, may be connected to the first inverter IV1, and the other one, for example, the second input end In2, may be connected to an enable terminal VEN. The output end Out1 of the logic gate LG1 may be connected to the second inverter IV2. However, a position and type of the logic gate LG1 may change. As an example, the logic gate LG1 may be positioned in front of the ring type circuit RC1.

The ring oscillator 100A may include an input terminal VIN, the enable terminal VEN, and an output terminal VOUT that are connected to the ring type circuit RC1. The input terminal VIN may be connected to at least one of the inverters IV1-IVn. Although the input terminal VIN is connected to the second inverter IV2 in FIG. 2, this is exemplary. A position and number of an inverter connected to the input terminal VIN may change. The enable terminal VEN may be connected to the logic gate LG1 as described above. More specifically, the enable terminal VEN may be connected to the second input end In2 of the logic gate LG1. The output terminal VOUT may be connected to an end of the ring type circuit RC1. That is, the output terminal VOUT may be connected to the output end of the last inverter IVn. An output inverter IVout may be further disposed between the ring type circuit RC1 and the output terminal VOUT. The ring oscillator 100A may not include the output inverter IVout.

The non-volatile memory element 200 may be connected to the input terminal VIN. The non-volatile memory element 200 may be connected between the input terminal VIN and the ring type circuit RC1. In this case, the non-volatile memory element 200 may be connected to at least one of the inverters IV1-IVn of the ring type circuit RC1. For example, the non-volatile memory element 200 may be connected to the second inverter IV2. The input terminal VIN may be connected to the second inverter IV2 through the non-volatile memory element 200. A position and number of an inverter connected to the non-volatile memory element 200 may change.

A resistance state of the non-volatile memory element 200 may change by applying a voltage to the non-volatile memory element 200 through the input terminal VIN. That is, a set voltage and a reset voltage may be applied to the non-volatile memory element 200 through the input terminal VIN. If the set voltage is applied to the non-volatile memory element 200, the non-volatile memory element 200 may have an ON state. If the reset voltage is applied to the non-volatile memory element 200, the non-volatile memory element 200 may have an OFF state. In a case where the non-volatile memory element 200 has a multi-bit memory characteristic, the non-volatile memory element 200 may have a plurality of OFF states.

During the change in the resistance state of the non-volatile memory element 200 through the input terminal VIN, the ring oscillator 100A may not operate. That is, the set voltage and the reset voltage may prevent the ring oscillator 100A from undesirably operating. For example, if a desired (or alternatively, predetermined) operation signal (i.e., an operation voltage) is not applied to the enable terminal VEN when the set voltage or the reset voltage is applied to the input terminal VIN, the ring oscillator 100A may not operate. After the non-volatile memory element 200 is in a desirable resistance state, if a desired (or alternatively, predetermined) operation voltage is applied to each of the input terminal VIN and the enable terminal VEN, the ring oscillator 100A may operate. A voltage applied to the input terminal VIN in order to operate the ring oscillator 100A may not change the resistance state of the non-volatile memory element 200. For example, the voltage applied to the input terminal VIN in order to operate the ring oscillator 100A may be higher than the set voltage and lower than the reset voltage. Thus, during the operation of the ring oscillator 100A, the resistance state of the non-volatile memory element 200 may not change.

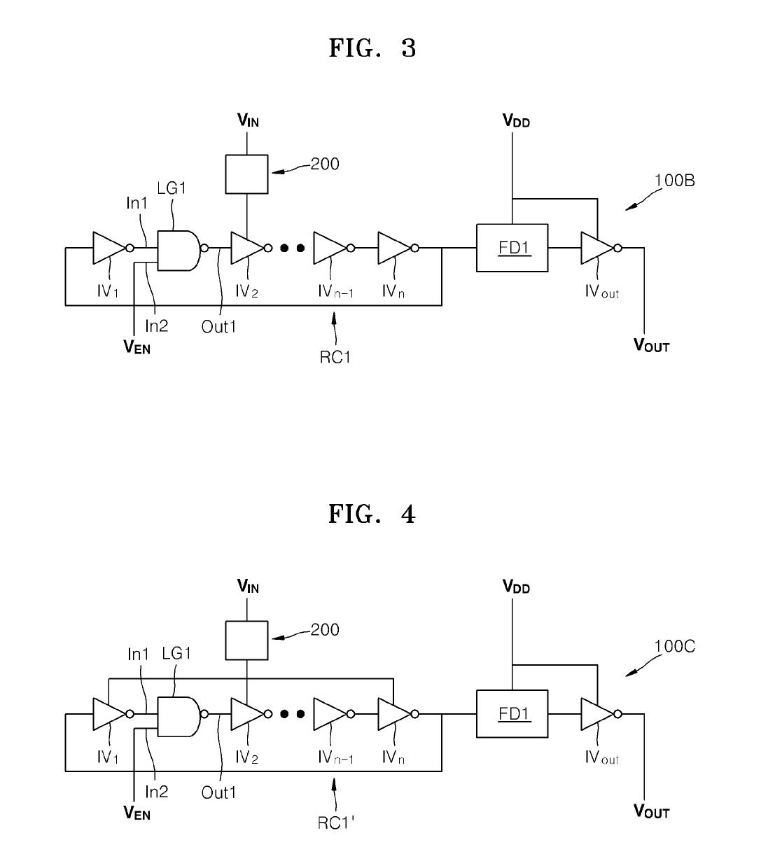

FIG. 3 is a circuit diagram of the frequency tuning apparatus of FIG. 1 according to another example embodiment. The circuit of FIG. 3 is a modification of the circuit of FIG. 2.

Referring to FIG. 3, the ring oscillator 100B may include a frequency divider FD1 connected between the ring type circuit RC1 and the output terminal VOUT. The frequency divider FD1 may be disposed between the ring type circuit RC1 and the output inverter IVout. The frequency divider FD1 may be an analog or a digital frequency divider. A power terminal VDD (i.e., a power source having a supply voltage VDD) may be connected to the frequency divider FD1. The power terminal VDD may also be connected to the output inverter IVout. Thus, the power terminal VDD may be in common connected to the frequency divider FD1 and the output inverter IVout. However, the power terminal VDD may be connected to only the frequency divider FD1 and may not be connected to the output inverter IVout.

The frequency divider FD1 may have a function of dividing a frequency of an input signal. That is, the frequency divider FD1 may be a device for receiving an input signal having a desired (or alternatively, predetermined) first frequency fᵢₙ and generating an output signal having a second frequency fₒᵤₜ. The second frequency fₒᵤₜ may correspond to a value obtained by dividing the first frequency fᵢₙ by n. In this regard, n may be an integer. Thus, the frequency divider FD1 may divide a frequency of a signal input into the frequency divider FD1 from the ring type circuit RC1.

The circuits of the frequency tuning apparatus of FIGS. 2 and 3 may be modified in various ways. As an example, the frequency tuning apparatus of FIG. 3 may be modified to that of FIG. 4. FIG. 4 is a circuit diagram of the frequency tuning apparatus of FIG. 3 having a modified ring type circuit RC1′.

Referring to FIG. 4, the first inverter IV1 and the last inverter IVn of the ring type circuit RC1′ may be connected to each other via body terminals thereof. Differently from a connection of the output end of the last inverter IVn to the input end of the first inverter IV1, the body terminal of the first inverter IV1 and the body terminal of the last inverter IVn may be connected to each other. In this regard, the body terminals indicate terminals of the inverters IV1 and IVn excluding the input and output ends thereof. The ring oscillator 100C includes the ring type circuit RC1′.

In a case where the body terminal of the first inverter IV1 and the body terminal of the last inverter IVn are connected to each other as shown in FIG. 4, the first inverter IV1 and the last inverter IVn may be connected to the non-volatile memory element 200. The non-volatile memory element 200 is connected to the input terminal VIN, and thus the first inverter IV1 and the last inverter IVn may be connected to the input terminal VIN through the non-volatile memory element 200. However, the first inverter IV1 and the last inverter IVn may not be connected to the non-volatile memory element 200 and the input terminal VIN.

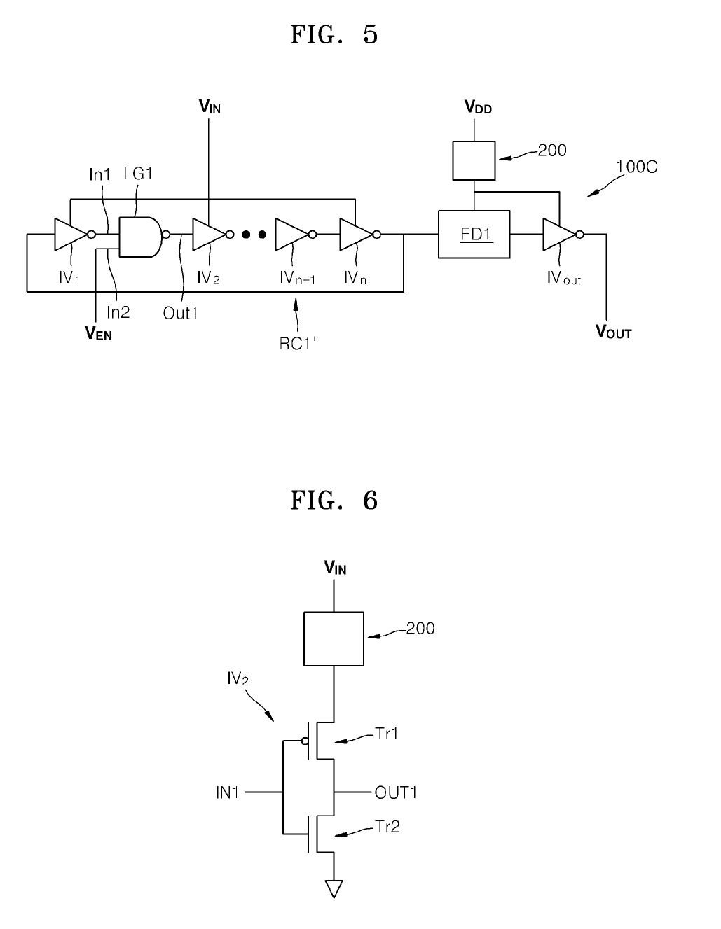

Although the non-volatile memory element 200 is connected to the input terminal VIN in FIGS. 2 through 4, a connection relationship between the non-volatile memory element 200 and the ring oscillators 100A-100C may change. For example, the non-volatile memory element 200 of FIG. 4 may be connected to the power terminal VDD rather than to the input terminal VIN. An example thereof is shown in FIG. 5.

Referring to FIG. 5, the non-volatile memory element 200 may be connected to the power terminal VDD. The non-volatile memory element 200 may be connected between the power terminal VDD and the frequency divider FD1. In this case, the output inverter IVout may be connected between the non-volatile memory element 200 and the frequency divider FD1. Meanwhile, the input terminal VIN may be directly connected to the ring type circuit RC1′.

A connection relationship between the non-volatile memory element 200 and the second inverter IV2 of the frequency tuning apparatus of FIGS. 2 through 4 will now be described in detail with reference to FIG. 6.

Referring to FIG. 6, the second inverter IV2 may include two transistors (hereinafter referred to as a first transistor and a second transistor) Tr1 and Tr2 that are connected to each other. The first transistor Tr1 may be a first type transistor. The second transistor Tr2 may be a second type transistor. For example, the first transistor Tr1 may be a p-type transistor, and the second transistor Tr2 may be an n-type transistor. A drain of the first transistor Tr1 may be connected to the input terminal VIN of the frequency tuning apparatus. The non-volatile memory element 200 may be connected between the drain of the first transistor Tr1 and the input terminal VIN. A gate of the first transistor Tr1 and a gate of the second transistor Tr2 may be commonly connected to the input end IN1 of the second inverter IV2. A source of the first transistor Tr1 and a drain of the second transistor Tr2 may be commonly connected to the output end OUT1 of the second inverter IV2. A source of the second transistor Tr2 may be grounded. The construction of the second inverter IV2 and the connection relationship between the non-volatile memory element 200 and the second inverter IV2 of FIG. 6 are merely exemplary. The construction of the second inverter IV2 may be modified in various ways. The connection relationship between the non-volatile memory element 200 and the second inverter IV2 may change.

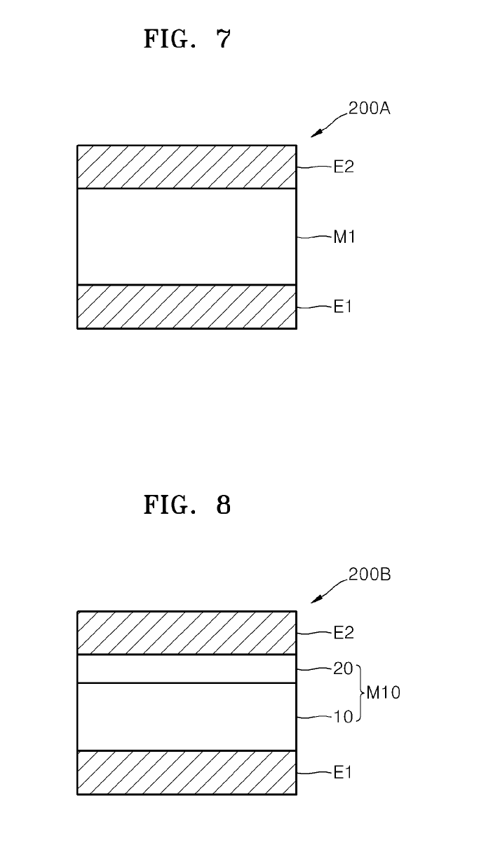

Hereinafter, a variety of structures of the non-volatile memory element 200 of FIGS. 1 through 6 will now be described with reference to FIGS. 7 through 11.

FIG. 7 is a cross-sectional view of an exemplary structure of the non-volatile memory element 200 of FIGS. 1 through 6.

Referring to FIG. 7, a non-volatile memory element 200A may include a first electrode E1 and a second electrode E2 that are spaced apart from each other and a memory layer M1 disposed between the first electrode E1 and the second electrode E2. The memory layer M1 may include a material having a resistance that varies according to an applied voltage, i.e., a variable resistance material. The variable resistance material may be used in a resistance random access memory (RRAM). The variable resistance material may be, for example, an oxide. More specifically, the memory layer M1 may include at least one of Ni oxide, Cu oxide, Ti oxide, Co oxide, Hf oxide, Zr oxide, Zn oxide, W oxide, Nb oxide, TiNi oxide, LiNi oxide, Al oxide, InZn oxide, V oxide, SrZr oxide, SrTi oxide, Cr oxide, Fe oxide, Ta oxide, and Si oxide. The oxide of the memory layer M1 may have a non-stoichiometric composition. The memory layer M1 may have a multi-bit memory characteristic. However, in certain cases, the memory layer M1 may have a single bit memory characteristic. Meanwhile, the first electrode E1 and the second electrode E2 may be formed of various metals or conductive oxides, etc.

Although the memory layer M1 has a single layer structure in FIG. 7, the memory layer M1 may have a multilayer structure. An example thereof is shown in FIG. 8.

Referring to FIG. 8, a memory layer M10 of a non-volatile memory element 200B may have a multilayer structure. For example, the memory layer M10 may have a double layer structure including a first material layer 10 and a second material layer 20. The memory layer M10 may have a resistance change characteristic due to movement of ionic species between the first material layer 10 and the second material layer 20. In this regard, the ionic species may include oxygen ions and/or oxygen vacancies.

The first material layer 10 may be formed of a first metal oxide. For example, the first material layer 10 may include at least one from among Ta oxide, Zr oxide, Y oxide, yttria-stabilized zirconia (YSZ), Ti oxide, Hf oxide, Mn oxide, Mg oxide, and a mixture thereof. In a case where the first metal oxide includes the Ta oxide, the first metal oxide may be TaOx (0<x<2.5 or 0.5≦x≦2.0). In a case where the first metal oxide includes the Ti oxide, the first metal oxide may be TiOx (0<x<2.0 or 0.5≦x≦1.5). Oxygen ions and/or oxygen vacancies may exist in the first material layer 10. The first material layer 10 may function as an oxygen-supplying layer with respect to the second material layer 20. The first material layer 10 may also be referred to as an oxygen reservoir layer. The first material layer 10 may be a layer doped with a desired (or alternatively, predetermined) metal. In this regard, the doping metal is a metal different from a base material (metal) constituting the first material layer 10. The metal may be tungsten (W), for example. The thickness of the first material layer 10 may be from about 1 nm to about 100 nm, for example, from about 5 nm to about 50 nm.

The second material layer 20 may exchange oxygen ions and/or oxygen vacancies with the first material layer 10 and induce resistance change of the memory layer M10. In this regard, the second material layer 20 may be referred to as an oxygen-exchanging layer. The second material layer 20 may be formed of a second metal oxide, which is the same kind as or a different kind from the first metal oxide. For example, the second metal oxide may contain at least one of Ta oxide, Zr oxide, Y oxide, YSZ, Ti oxide, Hf oxide, Mn oxide, Mg oxide, and a mixture thereof. The second metal oxide may have a stoichiometric composition or a composition similar thereto. For example, the Ta oxide of the second metal oxide may be Ta2O5 or may have a composition similar to Ta2O5. The Ti oxide of the second metal oxide may be TiO2 or may have a composition similar to TiO2. Similar to the first material layer 10, the second material layer 20 may contain oxygen ions and/or oxygen vacancies. Oxygen mobility (or oxygen diffusivity) of the second material layer 20 may be equal to or greater than that of the first material layer 10. Resistivity of the second material layer 20 may differ from that of the first material layer 10. For example, the resistivity of the second material layer 20 may be greater than that of the first material layer 10. In the ON state in which a current path (i.e., a filament) is formed in the second material layer 20, the electric resistance of the memory layer M10 may be determined by the electric resistance of the first material layer 10. In the OFF state in which no current path (i.e., a filament) exists in the second material layer 20, the electric resistance of the memory layer M10 may be determined by the electric resistance of the second material layer 20. Oxygen concentration of the second material layer 20 may be higher than that of the first material layer 10. However, in certain cases, the oxygen concentration of the second material layer 20 may not be higher than that of the first material layer 10. In a case where the second material layer 20 is formed of the same metal oxide as the first material layer 10, the oxygen concentration of the second material layer 20 may be higher than that of the first material layer 10. However, in a case where the second material layer 20 is formed of a metal oxide different from that of the first material layer 10, the oxygen concentration of the second material layer 20 is not necessarily higher than that of the first material layer 10. At least a portion of the second material layer 20 may be doped with a desired (or alternatively, predetermined) metal. In this regard, the doping metal is a metal different from a base material (metal) constituting the second material layer 20. The metal may be tungsten (W), for example. The second material layer 20 may have a multilayer structure. In this case, the second material layer 20 may include a first oxygen-exchanging layer and a second oxygen-exchanging layer. The first oxygen-exchanging layer and the second oxygen-exchanging layer may be formed of different metal oxides. The thickness of the second material layer 20 may be less than that of the first material layer 10. The thickness of the second material layer 20 may be from about 1 nm to about 50 nm, for example, from about 5 nm to about 20 nm.

The first electrode El may be formed of a base metal, such as W, Ni, Al, Ti, Ta, Mo, TiN, TiW, TaN, etc., or a conductive oxide, such as indium zinc oxide (IZO), indium tin oxide (ITO), etc. Alternatively, the first electrode E1 may be formed of a noble metal. For example, the first electrode E1 may be formed of a noble metal, such as Ir, Ru, Pd, Au, Pt, etc., or a metal oxide, such as IrO2. Therefore, the first electrode E1 may include at least one selected from a group consisting of W, Ni, Al, Ti, Ta, Mo, TiN, TiW, TaN, IZO, ITO, Ir, Ru, Pd, Au, Pt, and IrO2. Furthermore, although not stated herein, the first electrode El may be formed of any of various electrode materials commonly used in semiconductor devices. Similar to the first electrode E1, the second electrode E2 may be formed of one of various materials. For example, the second electrode E2 may be formed of a noble metal, such as Ir, Ru, Pd, Au, and Pt, a metal oxide, such as IrO2, a non-noble metal (i.e., a base metal), such as W, Ni, Al, Ti, Ta, Mo, TiN, TiW, and TaN, or a conductive oxide, such as IZO and ITO. However, materials constituting the second electrode E2 are not limited to the above-stated materials, and may vary.

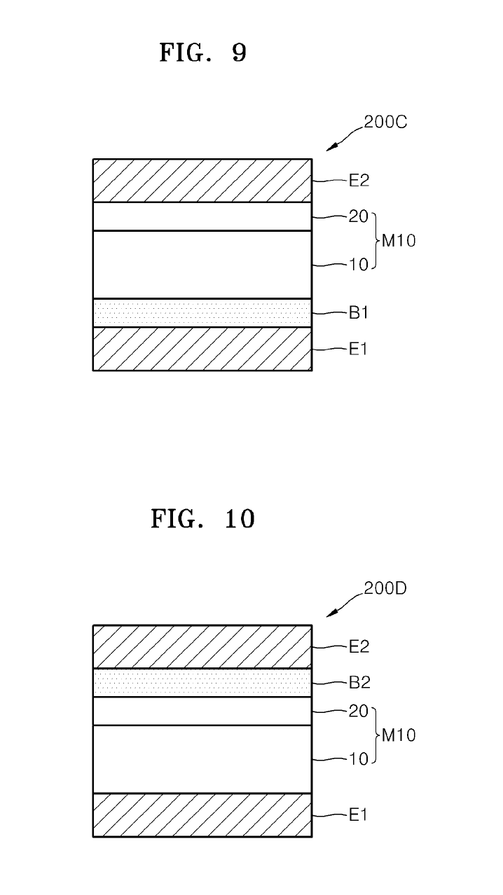

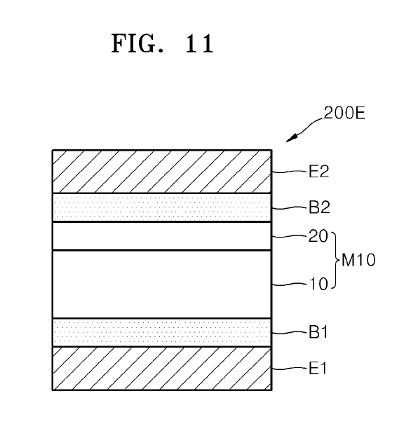

In FIG. 8, a desired (or alternatively, predetermined) buffer layer may be further disposed in at least one of between the memory layer M10 and the first electrode E1 and between the memory layer M10 and the second electrode E2. Examples thereof are shown in FIGS. 9 through 11. In FIG. 9, a first buffer layer B1 is disposed between the memory layer M10 and the first electrode E1. In FIG. 10, a second buffer layer B2 is disposed between the memory layer M10 and the second electrode E2. In FIG. 11, both the first buffer layer B1 and the second buffer layer B2 are disposed.

Referring to FIG. 9, the first buffer layer B1 of a non-volatile memory element 200C may improve reliability, reproducibility, and stability of resistance change characteristics of the memory layer M10. The first buffer layer B1 may include a material with a greater interatomic bonding energy than the memory layer M10. In other words, the interatomic bonding energy of the first buffer layer B1 may be greater than the interatomic (e.g., Ta-O) bonding energy of the first material layer 10. In other words, the first buffer layer B1 may be formed of a material that is more stable than the memory layer M10 in terms of bonding energy. Furthermore, the first buffer layer B1 may include a material that raises the potential barrier between the first electrode E1 and the memory layer M10. In other words, a conduction band offset between the first buffer layer B1 and the first electrode E1 may be greater than that between the first material layer 10 and the first electrode E1. In other words, the first buffer layer B1 may be formed of a material that suppresses an excessive current flow between the first electrode E1 and the first material layer 10. In order to get a similar effect, the first buffer layer B1 may include a material with higher resistivity than the memory layer M10. For example, the first buffer layer B1 may include at least one of AlOx, SiOx, SiNx, ZrOx, HfOx, and a mixture thereof. The first buffer layer B1 may or may not have a stoichiometric composition. The first buffer layer B1 may have a suitable composition and thickness to function as a buffer and to allow flow of electric current. The thickness of the first buffer layer B1 may be less than or equal to about 10 nm, for example. If the first buffer layer B1 has a stoichiometric composition, the thickness of the first buffer layer B1 may be less than or equal to about 5 nm. If the first buffer layer B1 has an excessive thickness, insulation properties of the first buffer layer B1 may undesirably increase. Therefore, as described above, the first buffer layer B1 may be formed to have a thickness less than or equal to about 10 nm. The description of the first buffer layer B1 described with reference to FIG. 9 may apply to that of the first buffer layer B1 of FIG. 11.

A material and function of the second buffer layer B2 of FIGS. 10 and 11 may be similar to (or the same as) those of the first buffer layer B1 of FIG. 9. The second buffer layer B2 of FIGS. 10 and 11 may also be a layer doped with a desired (or alternatively, predetermined) metal. The metal doped in the second buffer layer B2 may be, for example, tungsten (W). The second buffer layer B2 of FIGS. 10 and 11 may provide the memory layer M10 with a multi-bit memory characteristic, That is, the non-volatile memory elements 200D and 200E of FIGS. 10 and 11 may have a multi-bit memory characteristic by the second buffer layer B2. In this case, the second buffer layer B2 may be an auxiliary layer for providing a multi-bit memory characteristic.

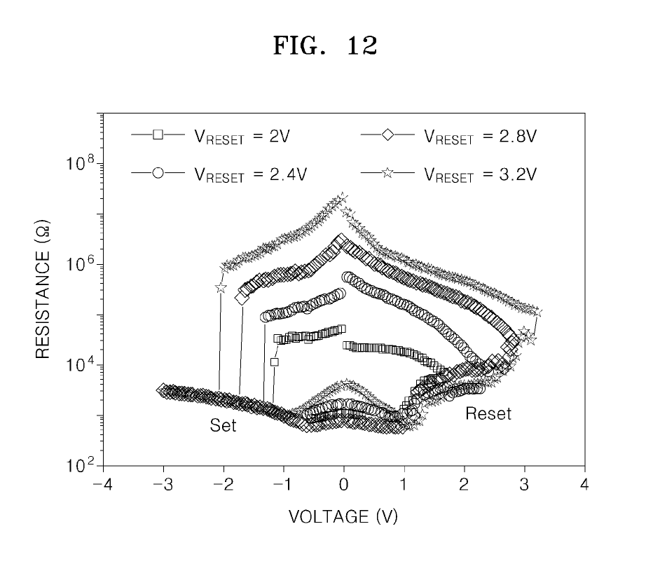

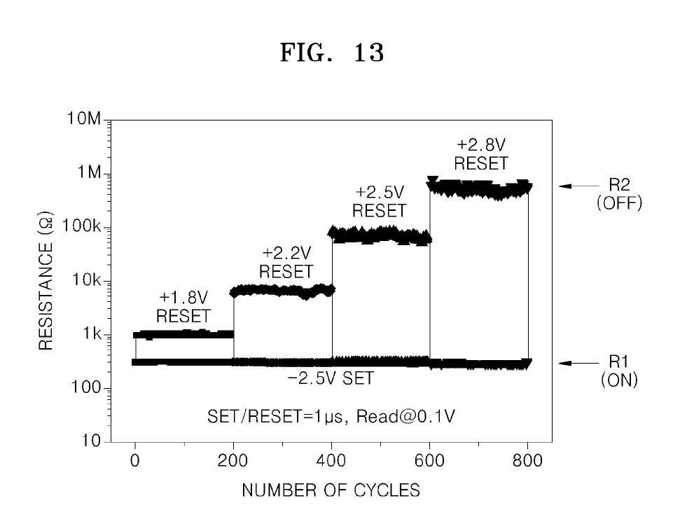

The non-volatile memory elements 200A-200E of FIGS. 7 through 11 may be a kind of memristors. The non-volatile memory elements 200A-200E may be elements having resistance states that vary according to whether a filament (i.e., a current path) is generated in the memory layers M1 and M10 and a state of the filament. In this configuration, the non-volatile memory elements 200A-200E may be filament type memory elements. Such a filament type memory element may have a gradual reset operation characteristic, and thus the filament type memory element may have resistance states of various levels by controlling a reset voltage. Thus, as described above, the non-volatile memory elements 200A-200E may have a multi-bit memory characteristic. The multi-bit memory characteristic of the non-volatile memory elements 200A-200E will now be described with reference to FIGS. 12 and 13.

FIG. 12 is a graph of a voltage-resistance characteristic of a non-volatile memory element having a structure of FIG. 8. The non-volatile memory element used to obtain a result of FIG. 12 has the structure of FIG. 8 and uses TiN, TiOx, TiOy, and Ir as materials constituting the first electrode E1, the first material layer 10, the second material layer 20, and the second electrode E2, respectively. In this regard, x of TiOx is less than y of TiOy. FIG. 12 shows the result measured by varying a reset voltage VRESET to 2V, 2.4V, 2.8V, and 3.2V in a direct current (DC) mode.

Referring to FIG. 12, as the reset voltage VRESET varies to 2V, 2.4V, 2.8V, and 3.2V, a resistance state of the non-volatile memory element changes. Provided that a resistance of the non-volatile memory element reset at 2V is a first resistance, a resistance thereof reset at 2.4V is a second resistance, a resistance thereof reset at 2.8V is a third resistance, and a resistance thereof reset at 3.2V is a fourth resistance, the first through fourth resistances are clearly different from each other. As such, an OFF resistance level of the non-volatile memory element is divided into various levels according to levels of an operation voltage (i.e., the reset voltage VRESET). A plurality of OFF resistance levels of the non-volatile memory element may correspond to a plurality of pieces of data. Thus, the non-volatile memory element may have a characteristic of a multi-bit memory. In addition, the non-volatile memory element is set at a voltage from about −2V to about −1V in FIG. 12. A resistance, i.e., an ON resistance, of the set non-volatile memory element is not divided into various levels.

FIG. 13 is a graph of variations of ON and OFF resistances of a non-volatile memory element having a structure of FIG. 8 for each of switching conditions. The non-volatile memory element used to obtain a result of FIG. 13 is the same as the non-volatile memory element of FIG. 12. The variations of the ON and OFF resistances of the non-volatile memory element are measured by varying the reset voltage VRESET to 1.8V, 2.2V, 2.5V, and 2.8V. A set voltage VSET is −2.5V, an application time per voltage pulse (a pulse width) is 1 μs, and a read voltage is 0.1V. In the graph for each switching condition of FIG. 13, a low resistance level R1 indicates an ON resistance level, and a high resistance level R2 indicates an OFF resistance level. The result of FIG. 13 corresponds to measurements obtained in an alternating current (AC) mode.

As shown in the result of FIG. 13, an OFF resistance level varies according to switching conditions. That is, various OFF resistance levels appear according to an intensity of the reset voltage VRESET. This means that the non-volatile memory element may have various resistance states according to switching conditions. In this regard, the non-volatile memory element may have four or more resistance states. That is, the non-volatile memory element may have four or more resistance states corresponding to data “00”, “01”, “10”, and “11”. For example, the ON resistance level may correspond to the data “00”, in the reset voltage VRESET of 1.8V, the OFF resistance level may correspond to the data “01”, in the reset voltage VRESET of 2.2V, the OFF resistance level may correspond to the data “10”, and in the reset voltage VRESET of 2.5V, the OFF resistance level may correspond to the data “11”. Alternatively, in the reset voltage VRESET of 1.8V, the OFF resistance level may correspond to the data “00”, in the reset voltage VRESET of 2.2V, the OFF resistance level may correspond to the data “01”, in the reset voltage VRESET of 2.5V, the OFF resistance level may correspond to the data “01”, and in the reset voltage VRESET of 2.8V, the OFF resistance level may correspond to the data “11”. Thus, the non-volatile memory element may have a characteristic of a multi-bit memory. The above-described correspondence (matching) of the resistance levels and the data is exemplary and may be modified.

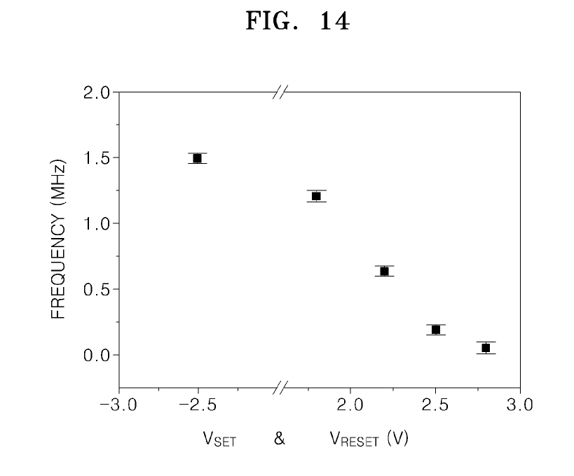

FIG. 14 is a graph of a variation of an oscillation frequency of a frequency tuning apparatus including a non-volatile memory element with respect to set and reset voltages of the non-volatile memory element according to an example embodiment. FIG. 14 shows a result obtained from the frequency tuning apparatus having the circuit construction of FIG. 4. The ring oscillator 100C used herein is a 65 nm complementary metal-oxide-semiconductor (CMOS) logic device and has forty (40) inverting states and a frequency divider of eight (8) states. Also, the non-volatile memory element 200 is the same as the non-volatile memory element (i.e., a TiN/TiOx/TiOy/Ir structure) used to obtain the result of FIG. 13. After the non-volatile memory element 200 is set or reset, a voltage of 1V is applied to all of the input terminal VIN, the enable terminal VEN, and the power terminal VDD to operate the frequency tuning apparatus, and then the oscillation frequency of the frequency tuning apparatus is measured.

Referring to FIG. 14, the oscillation frequency of the frequency tuning apparatus varies according to a change in voltages (the set and reset voltages) applied to the non-volatile memory element 200. The higher the voltages (set and reset voltages) applied to the non-volatile memory element 200, the lower the oscillation frequency. FIG. 14 shows that as the voltages (the set and reset voltages) applied to the non-volatile memory element 200 increase, a resistance of the non-volatile memory element 200 may increase, which may result in a reduction in the oscillation frequency.

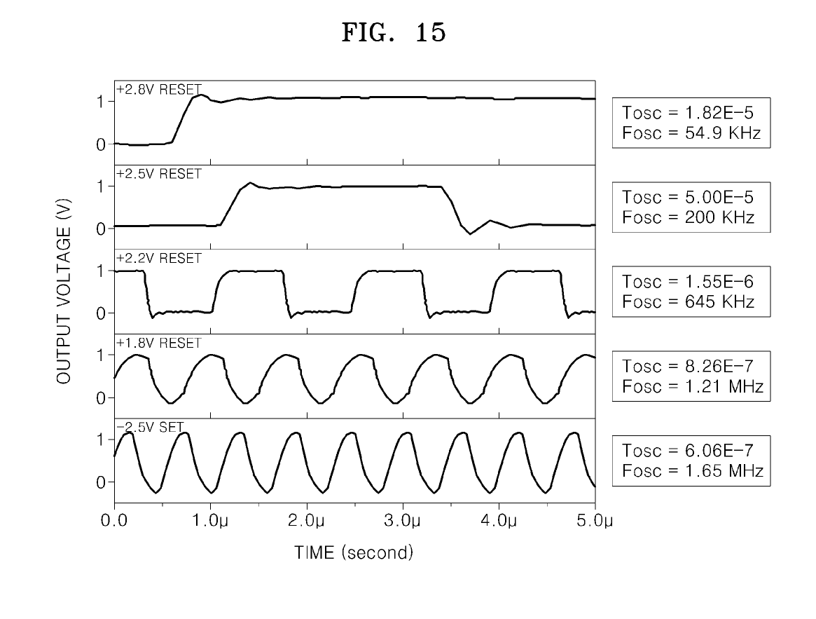

FIG. 15 is a waveform diagram of a variation of an oscillation frequency FOSC of a frequency tuning apparatus including a non-volatile memory element with respect to set and reset voltages of the non-volatile memory element according to an example embodiment, which corresponds to the result of FIG. 14.

Referring to FIG. 15, the oscillation frequency FOSC of the frequency tuning apparatus varies according to a change in voltages (the set and reset voltages) applied to the non-volatile memory element. The higher the voltages (the set and reset voltages) applied to the non-volatile memory element, the lower the oscillation frequency FOSC, and the greater the oscillation cycle TOSC (sec). Meanwhile, although the reset voltage varies, amplitude of a wave remains relatively unchanged.

The frequency tuning apparatus according to an example embodiment of the may obtain the oscillation frequency corresponding to a resistance state of the non-volatile memory element by changing the resistance state to a desired state and operating an oscillator (a ring oscillator). If the resistance state of the non-volatile memory element is changed to a desired (or alternatively, predetermined) first state, the desired (or alternatively, predetermined) first state may remain unchanged until the desired (or alternatively, predetermined) first state is forcibly changed (by a set or reset operation). Even if the oscillator (the ring oscillator) oscillates, the resistance state of the non-volatile memory element may remain unchanged. Further, even if the resistance state of the non-volatile memory element is changed, a condition (a voltage condition) for oscillating the oscillator (the ring oscillator) may be the same. For example, a voltage applied to the input terminal VIN so as to oscillate the oscillator if the non-volatile memory element is in the first resistance state, and a voltage applied to the input terminal VIN so as to oscillate the oscillator if the non-volatile memory element is in a second resistance state may be the same. In other words, the oscillation frequency may vary while the condition (the voltage condition) for oscillating the oscillator may not change. Thus, the frequency tuning apparatus according to an example embodiment may vary a frequency stably while performance of the oscillator in an RF system remains unchanged. In other words, the frequency tuning apparatus according to an example embodiment may have high performance and high reliability.

Moreover, the frequency tuning apparatus according to an example embodiment has a simple structure in which the non-volatile memory element is connected to the oscillator (the ring oscillator), and thus the frequency tuning apparatus may be easily manufactured and may easily scale down the RF system. Furthermore, an element for tuning a frequency (i.e., the non-volatile memory element) does not include a switching circuit, and thus the element may have a simple stack structure. Also, the element (i.e., the non-volatile memory element) may be operated by a simple method, thereby reducing power consumption for tuning a frequency and simplifying a construction of a peripheral circuit.

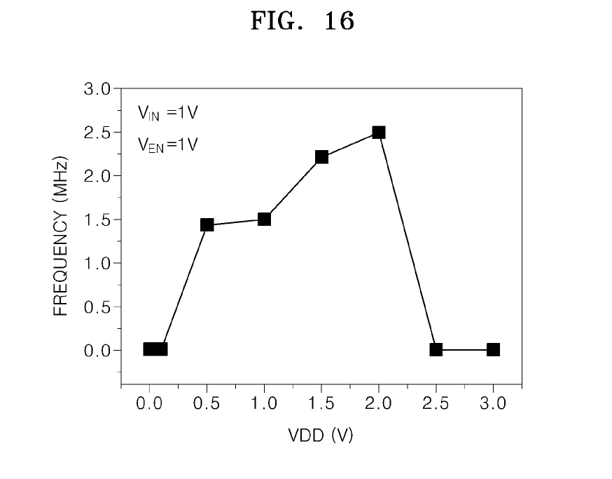

FIG. 16 is a graph of a variation of an oscillation frequency with respect to a change of a voltage VDD applied to the power terminal VDD of the frequency tuning apparatus having a circuit construction of FIG. 5. In an example embodiment according to FIG. 16, a voltage of 1V is applied to both the input terminal VIN and the enable terminal VEN.

Referring to FIG. 16, the oscillation frequency varies with respect to a change of the voltage VDD applied to the power terminal VDD. This result shows that even though the non-volatile memory element 200 is connected to the power terminal VDD, the oscillation frequency may vary according to a resistance state of the non-volatile memory element 200. That is, if the resistance state of the non-volatile memory element 200 of FIG. 5 varies, accordingly, a valid power voltage applied to the ring oscillator 100C changes, and thus the oscillation frequency may vary as shown in FIG. 16.

A method of operating the frequency tuning apparatus according to an example embodiment described above will now be briefly described.

The frequency tuning apparatus (i.e., the frequency tuning apparatus described with reference to FIGS. 1 through 11) according to an example embodiment may include an oscillator and a non-volatile memory element connected to the oscillator. The method of operating the frequency tuning apparatus may include an operation of varying a resistance state of the non-volatile memory element and an operation of operating the oscillator. After the resistance state of the non-volatile memory element is changed to a first state, an oscillation frequency corresponding to the first state may be obtained by operating the oscillator. Then, after the resistance state of the non-volatile memory element is changed to a second state, an oscillation frequency corresponding to the second state may be obtained by operating the oscillator. As such, various oscillation frequencies may be obtained by using a method of simply varying the resistance state of the non-volatile memory element. According to a method of an example embodiment, the non-volatile memory element may have a multi-bit memory characteristic. In this case, the non-volatile memory element may have multiple OFF states according to a reset voltage. Thus, various resistance states may be obtained by resetting the non-volatile memory element at various voltages. However, the non-volatile memory element may not necessarily have a multi-bit memory characteristic. In certain cases, a non-volatile memory element having a single bit memory characteristic may be used. Detailed constructions of the non-volatile memory element and the oscillator are the same as described with reference to FIGS. 1 through 11, and thus redundant descriptions are omitted here.

The frequency tuning apparatus according to an example embodiment may be applied to various RF circuits. For example, the frequency tuning apparatus according to an example embodiment may be applied to an RF filter. The RF filter to which the frequency tuning apparatus according to an example embodiment is applied may be understood by one of ordinary skill in the art, and thus a detailed description thereof is omitted here. The frequency tuning apparatus according to an example embodiment may be applied to an RF circuit other than the RF filter or another circuit instead of the RF circuit for various purposes.

While example embodiments have been particularly shown and described, it will be understood by one of ordinary skill in the art that various changes in form and details may be made therein without departing from the spirit and scope of the example embodiments as defined by the following claims. For example, it would be obvious to one of ordinary skill in the art that the construction of the frequency tuning apparatus of FIGS. 1 through 5 may be modified in various ways. For example, the constructions of the ring oscillators 100A-100C may be modified in various ways, and oscillators having different structures may be applied instead of the ring oscillators 100A-100C. Furthermore, it would be obvious to one of ordinary skill in the art that constructions and materials of the non-volatile memory elements 200A-200E of FIGS. 7 through 11 may be modified in various ways. For example, the non-volatile memory elements 200A-200E, as a resistive memory element used in an RRAM, may be replaced with memory elements used in a phase-change random access memory (PRAM), a magnetic random access memory (MRAM), or a ferroelectric random access memory (FRAM), etc. Therefore, the scope of the example embodiments are defined not by the above detailed description but by the appended claims, and all differences within the scope will be construed as being included in the inventive concepts.

What is claimed is:

1. A frequency tuning apparatus comprising:
an oscillator; and
a memory element connected to the oscillator and having a variable resistance, an oscillation frequency of the oscillator varying according to a resistance state of the memory element.

2. The frequency tuning apparatus of claim 1, wherein the memory element is a multi-bit memory element.

3. The frequency tuning apparatus of claim 1, wherein the memory element includes a plurality of OFF states.

4. The frequency tuning apparatus of claim 1, wherein the resistance state of the memory element varies according to a reset voltage.

5. The frequency tuning apparatus of claim 1, wherein the memory element comprises:
a first electrode and a second electrode; and
a memory layer between the first electrode and the second electrode, a resistance of the memory layer varying according to a voltage applied to the memory layer.

6. The frequency tuning apparatus of claim 5, wherein the memory layer comprises an oxide.

7. The frequency tuning apparatus of claim 5, wherein the memory layer has a single layer structure or a multi-layer structure.

8. The frequency tuning apparatus of claim 7, wherein the memory layer has the multi-layer structure, and the multi-layer structure comprises an oxygen-supplying layer and an oxygen-exchanging layer.

9. The frequency tuning apparatus of claim 8, wherein an oxygen concentration of the oxygen-exchanging layer is higher than that of the oxygen-supplying layer.

10. The frequency tuning apparatus of claim 8, wherein at least one of the oxygen-supplying layer and the oxygen-exchanging layer comprises at least one of Ta oxide, Zr oxide, Y oxide, yttria-stabilized zirconia (YSZ), Ti oxide, Hf oxide, Mn oxide, Mg oxide, and a mixture thereof.

11. The frequency tuning apparatus of claim 1, wherein the oscillator is a ring oscillator.

12. The frequency tuning apparatus of claim 11, wherein the oscillator comprises:
a ring type circuit in which a plurality of inverters are connected to each other in a ring configuration; and
an input terminal and an output terminal connected to the ring type circuit.

13. The frequency tuning apparatus of claim 12, wherein the memory element is connected to the input terminal.

14. The frequency tuning apparatus of claim 13, wherein the memory element is connected between the input terminal and at least one of the plurality of inverters.

15. The frequency tuning apparatus of claim 12, wherein the ring type circuit further comprises a logic gate, and the oscillator further comprises an enable terminal connected to the logic gate.

16. The frequency tuning apparatus of claim 15, wherein the logic gate is a NAND gate.

17. The frequency tuning apparatus of claim 12, further comprising:
an output inverter connected between the ring type circuit and an output terminal.

18. The frequency tuning apparatus of claim 17, further comprising:
a frequency divider connected between the ring type circuit and the output inverter.

19. The frequency tuning apparatus of claim 18, further comprising:
a power source connected to the frequency divider.

20. The frequency tuning apparatus of claim 19, wherein the power source is connected to the output inverter.

21. The frequency tuning apparatus of claim 12, wherein the oscillator further comprises a power source connected between the ring type circuit and the output terminal, and the memory element is connected to the power source.

22. The frequency tuning apparatus of claim 21, further comprising:
a frequency divider connected between the power source and the ring type circuit.

23. The frequency tuning apparatus of claim 22, further comprising:
an output inverter connected between the frequency divider and the output terminal.

24. A radio frequency (RF) circuit comprising the frequency tuning apparatus of claim 1.

25. The RF circuit of claim 24, wherein the RF circuit is an RF filter.

26. A method of operating the frequency tuning apparatus of claim 1, the method comprising:
varying a resistance state of the memory element; and
operating the oscillator according to the resistance state.
